(19) United States
(12) Patent Application Publication
(10) Pub. No.: US 2025/0379084 A1
(43) Pub. Date: Dec. 11, 2025

(54) INFORMATION PROCESSING APPARATUS, DETECTION METHOD, AND SUBSTRATE PROCESSING APPARATUS

(71) Applicant: Tokyo Electron Limited, Tokyo (JP)

(72) Inventors: Satoshi NAKAYAMA, Yamanashi (JP); Satoshi KATO, Iwate (JP)

(21) Appl. No.: 19/219,234

(22) Filed: May 27, 2025

(30) Foreign Application Priority Data
Jun. 5, 2024 (JP) 2024-091606

(51) Int. Cl. H01L 21/68; G06T 5/40; G06T 5/90; G06T 7/00; G06V 10/74; H04N 23/73

(52) U.S. Cl. CPC H01L 21/681; G06T 5/40; G06T 5/90; G06T 7/001; G06V 10/761; H04N 23/73

(57) ABSTRACT

An information processing apparatus includes an image capturing unit that captures an image of an interior of a processing chamber of an information processing apparatus through a window provided on a top surface of the processing chamber, thereby allowing the information processing apparatus to detect a predetermined image used for positioning a susceptor accommodated in the processing chamber from the image of the interior of the processing chamber; a similarity calculation unit that calculates a similarity between a current predetermined image included in the image of the interior of the processing chamber and an original predetermined image; a determination unit that determines a deterioration of the current predetermined image based on the similarity; and a correction unit that performs a correction process to improve a precision of detection of the predetermined image based on the deterioration of the current predetermined image.

### CROSS REFERENCES TO RELATED APPLICATIONS

This application is based on and claims priority from Japanese Patent Application No. 2024-091606, filed on Jun. 5, 2024, with the Japan Patent Office, the disclosure of which is incorporated herein in its entirety by reference.

### TECHNICAL FIELD

The present disclosure relates to an information processing apparatus, a detection method, and a substrate processing apparatus.

### BACKGROUND

In the related art, a substrate position detecting apparatus is known, which captures an image of a predetermined imaging target disposed in a substrate processing chamber through a window provided in the top surface of the chamber, and detects a position of a substrate from the image of the predetermined imaging target. In the substrate position detecting apparatus, a high-contrast image of the predetermined imaging target is captured to detect the position of the substrate, even when a deposition is performed in the chamber (see, e.g., Japanese Patent No. 6118102).

### SUMMARY

According to an embodiment of the present disclosure, an information processing apparatus includes: an image capturing unit that captures an image of an interior of a processing chamber of an information processing apparatus through a window provided on a top surface of the processing chamber, thereby allowing the information processing apparatus to detect a predetermined image used for positioning a susceptor accommodated in the processing chamber from the image of the interior of the processing chamber; a similarity calculation unit that calculates a similarity between a current predetermined image included in the image of the interior of the processing chamber and an original predetermined image; a determination unit that determines a deterioration of the current predetermined image based on the similarity calculated in the similarity calculation unit; and a correction unit that performs a correction process to improve a precision of detection of the predetermined image based on the deterioration of the current predetermined image determined at the determination unit.

The foregoing summary is illustrative only and is not intended to be in any way restricting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view schematically illustrating an example of a substrate processing apparatus according to an embodiment of the present disclosure.

FIG. 2 is a view schematically illustrating an example of the top surface of a chamber of the substrate processing apparatus according to an embodiment of the present disclosure.

FIGS. 3A and 3B are views illustrating an example of a substrate position detecting apparatus according to an embodiment of the present disclosure.

FIGS. 4A and 4B are views illustrating an example of an arrangement relationship of a chamber mark and a susceptor mark in the substrate processing apparatus according to an embodiment of the present disclosure.

FIG. 5 is a functional block diagram of an example of a processing unit according to an embodiment of the present disclosure.

FIGS. 6A and 6B are views illustrating histogram equalization.

FIGS. 7A and 7B are views illustrating histogram equalization of an image in which light and dark parts are clearly present.

FIGS. 8A and 8B are views illustrating an example of an image of a susceptor mark subjected to a general histogram equalization process or an adaptive histogram equalization process.

FIGS. 9A to 9C are views illustrating a process of adjusting a shutter speed of a camera according to an SSIM value.

FIGS. 10A to 10C are views illustrating a process of adjusting a binarization threshold used for detecting a susceptor mark according to an SSIM value.

FIG. 11 is a flowchart illustrating an example of a process procedure performed by the substrate position detecting apparatus according to an embodiment of the present disclosure.

FIG. 12 is a flowchart illustrating an example of a process procedure performed by the substrate position detecting apparatus according to an embodiment of the present disclosure.

FIG. 13 is a flowchart illustrating an example of a process procedure performed by the substrate position detecting apparatus according to an embodiment of the present disclosure.

FIG. 14 is a flowchart illustrating an example of a process procedure performed by the substrate position detecting apparatus according to an embodiment of the present disclosure.

FIG. 15 is a flowchart illustrating an example of a process procedure performed by the substrate position detecting apparatus according to an embodiment of the present disclosure.

FIG. 16 is a flowchart illustrating an example of a process procedure performed by the substrate position detecting apparatus according to an embodiment of the present disclosure.

FIG. 17 is a flowchart illustrating an example of a process procedure performed by the substrate position detecting apparatus according to an embodiment of the present disclosure.

FIG. 18 is a flowchart illustrating an example of a process procedure performed by the substrate position detecting apparatus according to an embodiment of the present disclosure.

FIG. 19 is a flowchart illustrating an example of a process procedure performed by the substrate position detecting apparatus according to an embodiment of the present disclosure.

FIG. 20 is a view illustrating an example of a configuration of a substrate processing system according to an embodiment of the present disclosure.

FIG. 21 is a diagram illustrating an example of a hardware configuration of a computer.

### DETAILED DESCRIPTION

In the following detailed description, reference is made to the accompanying drawings, which form a part hereof. The illustrative embodiments described in the detailed description, drawings, and claims are not meant to be restricting. Other embodiments may be utilized, and other changes may be made without departing from the spirit or scope of the subject matter presented here.

Hereinafter, an embodiment of the present disclosure will be described with reference to the drawings.

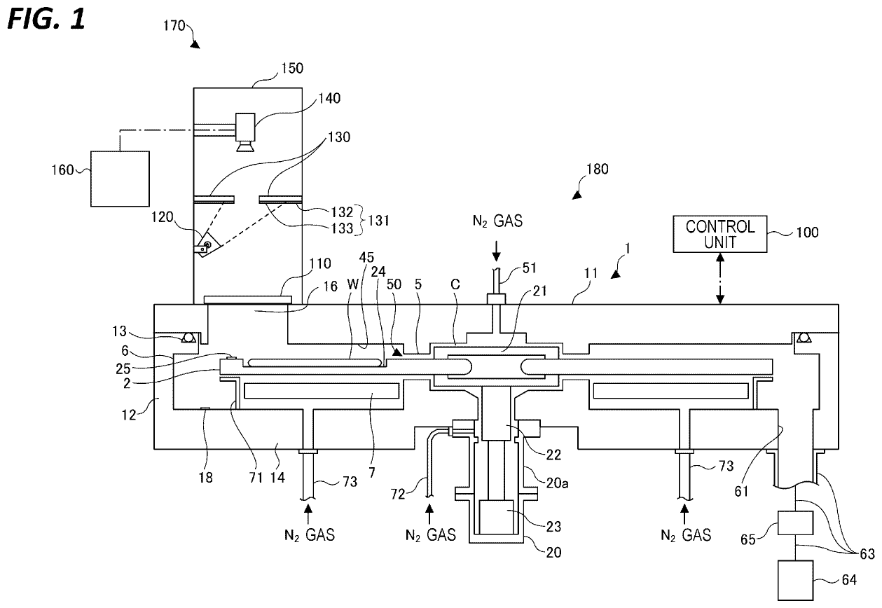

FIG. 1 is a view schematically illustrating an example of a substrate processing apparatus 180 according to an embodiment of the present disclosure. The substrate processing apparatus 180 includes a substrate position detecting apparatus 170. The substrate position detecting apparatus 170 includes a light 120, a light reflector 130, a camera 140, a housing 150, and a processing unit 160.

The substrate processing apparatus 180 further includes a chamber 1, a susceptor 2, a window 110, and a rotary shaft 22 as main components, in addition to the substrate position detecting apparatus 170. Further, the substrate processing apparatus 180 may include various components provided in the chamber 1 and various components attached to the chamber 1 as needed for substrate processing. FIG. 1 further illustrates a wafer W, which is an example of a substrate.

The chamber 1 is a processing container in which a processing is performed on substrates such as wafers W. The chamber 1 of the substrate processing apparatus 180 according to the present embodiment may be used for any type of substrate processing. Thus, the substrate processing apparatus 180 may be configured as an apparatus that performs various types of substrate processing. In the present embodiment, for ease of description, descriptions are made on an example where the chamber 1 of the substrate processing apparatus 180 is configured as a deposition chamber for performing a deposition.

The chamber 1 is configured as a sealed container in which wafers W are processed. The chamber 1 includes a ceiling plate 11 and a container body 12, and may make up a sealed container as a whole. In a portion of the ceiling plate 11, a hole 16 is formed to allow the camera 140 to capture an image of the interior of the chamber 1. The hole 16 is an opening allowing a communication with the interior of the chamber 1. The chamber 1 is sealed by disposing the window 110 to cover the hole 16.

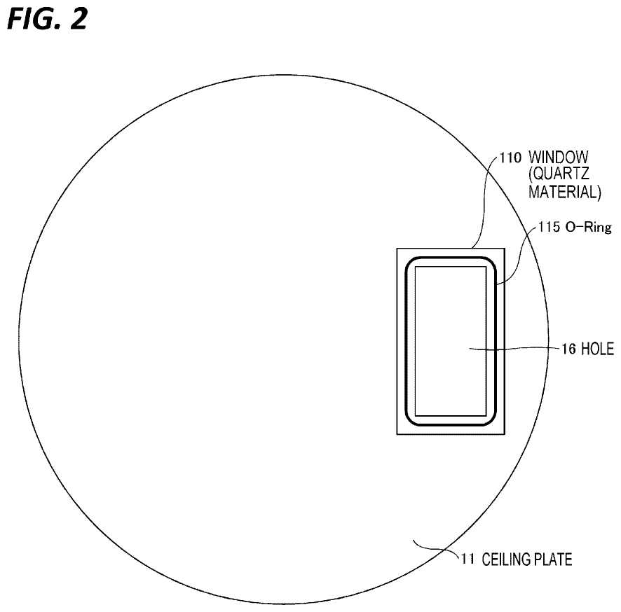

FIG. 2 is a view schematically illustrating an example of the top surface of the chamber 1 of the substrate processing apparatus 180 according to the present embodiment. The top surface of the chamber 1 is made up by the ceiling plate 11. The top surface of the chamber 1 has the hole 16 in a portion of the ceiling plate 11. Further, in the ceiling plate 11, the window 110 one time larger than the hole 16 is provided to cover the hole 16. The window 110 is sealed by an O-ring 115 while covering the hole 16.

Descriptions are made referring back to FIG. 1. When performing a deposition process, it is common to heat the inside of the chamber 1 to a high temperature, and supply a reaction gas for deposition into the chamber 1. In the present embodiment, descriptions will be made assuming an example where the deposition process uses the atomic layer deposition (ALD) method that forms an atomic layer on the surface of wafers W or the molecular layer deposition (MLD) method that forms a molecular layer on the surface of wafers W.

On the bottom surface of the chamber 1, a chamber mark 18 is provided as an example of a mark for indicating a reference position of the chamber 1. Details of the chamber mark 18 will be described herein later. The chamber 1 accommodates the susceptor 2.

The susceptor 2 is a substrate placement stage on which substrates are placed. The susceptor 2 is provided in the chamber 1. In the surface of the susceptor 2, a recess 24 is formed as a substrate placement region in which a wafer W may be placed, in a dented shape with substantially the same size as the wafer W. The recess 24 of the susceptor 2 is configured such that a wafer W is placed in a predetermined position. The susceptor 2 is formed in a circular disk shape, and configured such that a plurality of wafers W may be placed along the circumferential direction.

The susceptor 2 is connected to the rotary shaft 22, and configured to be rotatable. Since the susceptor 2 is rotatable, the position of a wafer W placed on the susceptor 2 is not fixed, and needs to be detected when the deposition process is performed. The wafer W is placed in the recess 24 of the susceptor 2.

Thus, a susceptor mark 25 is provided on the surface of the susceptor 2 as an example of a mark used for positioning the susceptor 2. By detecting the susceptor mark 25, the substrate processing apparatus 180 according to the present embodiment detects the position of the wafer W placed on the susceptor 2. Details of the susceptor mark 25 will be described herein later. Since the susceptor 2 has the circular shape, the chamber 1 accommodating the susceptor 2 also has a cylindrical shape.

The window 110 is provided over the hole 16, to block the opening formed by the hole 16 and secure an image capturing view of the camera 140 provided above through the top surface. The window 110 is made of various light-transmitting materials. The window 110 may be configured as, for example, a quartz window made of quartz glass.

The light 120 is a light source emitting light. The light 120 emits light upward toward the light reflector 130 disposed above the light 120, and the light reflected from the light reflector 130 enters through the window 110. As for the light 120, various light sources may be used as long as they may emit light with an appropriate luminance, and for example, a light emitting diode (LED) may be used. The light 120 is provided near the wall surface of the housing 150 so as not to obstruct the image capturing view of the camera 140, and emits light diagonally upward.

The light reflector 130 reflects the light incident from the light 120. The light reflector 130 illuminates the window 110 with the reflected light to brighten the interior of the chamber 1. The light reflector 130 reflects the light incident from below, and thus, has a reflection surface 131 on the lower surface thereof. In the reflection surface 131, the light reflector 130 may include not only a portion reflecting light, but also a reflection restricting portion that forms a shadow in a predetermined region within the image capturing view of the camera 140. The light reflector 130 has an opening 134 so as not to obstruct the image capturing view of the camera 140.

While FIG. 1 illustrates the light reflector 130 provided below the camera 140, the light reflector 130 may be provided above the camera 140. In this case, the opening 134 of the light reflector 130 is unnecessary. When the light reflector 130 is provided above the camera 140, the light reflector 130 may be formed in a single plate shape.

The camera 140 captures an image of the interior of the chamber 1 through the window 110. In the substrate position detecting apparatus 170 according to the present embodiment, the camera 140 may be any of cameras with various configurations according to applications such as a charge coupled device (CCD).

The housing 150 is a casing (frame) for accommodating the window 110, the light 120, the light reflector 130, and the camera 140. The housing 150 covers the entire substrate position detecting apparatus 170 to darken the surroundings of the camera 140 and enter the state suitable for the imaging.

Based on an image captured by the camera 140, the processing unit 160 performs calculation processes for detecting the positions of the chamber mark 18 and the susceptor mark 25 useful for positioning the susceptor 2 as described herein later. The processing unit 160 is, for example, a microcomputer equipped with a central processing unit (CPU) and operating by a program. The processing unit 160 may be configured as an integrated circuit such as an application specific integrated circuit (ASIC) designed and manufactured for a specific application.

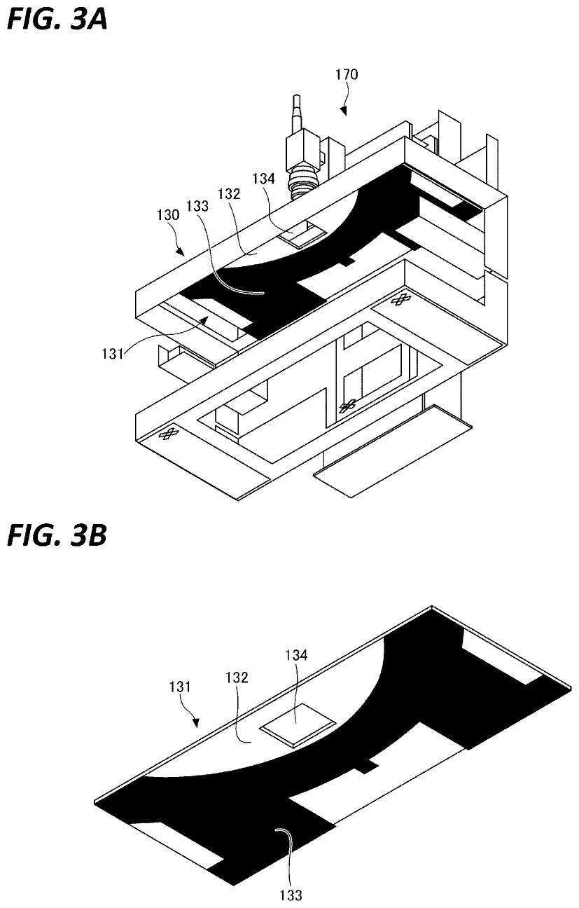

FIGS. 3A and 3B are views illustrating an example of the substrate position detecting apparatus 170 according to the present embodiment. FIG. 3A is a perspective view illustrating an example of the substrate position detecting apparatus 170 according to the present embodiment, when viewed from below.

As illustrated in FIG. 3A, the light reflector 130 has the lower surface as the reflection surface 131, since the light is irradiated from below. The reflection surface 131 includes a reflective portion 132, a reflection restricting portion 133, and the opening 134. The reflective portion 132 is a region for reflecting the illumination light, and is a portion that irradiates the window 110 with the reflected light to illuminate an imaging target. Meanwhile, the reflection restricting portion 133 is a region where the illumination light is not reflected even though being irradiated, to form a shadow in the corresponding region.

When the substrate processing apparatus 180 performs a deposition using the ALD or MLD method, a film is basically deposited only on the substrate placed on the susceptor 2, but is also deposited on the susceptor 2 supporting the substrate. When a film is deposited on the susceptor 2, the susceptor mark 25 is covered by the film, and is not clearly visible. For example, when a TiN film is deposited, the shading difference between the susceptor mark 25 formed on the susceptor 2 and its surrounding region decreases due to the film deposition, and thus, the contrast is reduced.

For example, the susceptor mark 25 with no film deposited thereon is clearly visible in a captured image. For example, in a state where a TiN film with a thickness of about 3 μm is deposited on the susceptor 2, the susceptor 2 turns black. Accordingly, the susceptor mark 25 assimilates with the color of the surrounding region so that the shading difference therebetween decreases, and consequently, becomes hard to see in a captured image. Further, in a state where a TiN film with a thickness of, for example, about 8 μm is deposited, a captured image of the susceptor mark 25 comes out white as a whole. Due to the reduced shading difference, the susceptor mark 25 becomes difficult to see in the captured image.

The film is also deposited in a small amount not only on the inner wall surface of the chamber 1 but also the inner surface of the window 110. When the TiN film having a reflexibility without transmitting light is deposited on the inner surface of the window 110, the light transmitting through the window 110 decreases so that the window 110 becomes like a mirror reflecting light. Thus, in the captured image, the entire region of the window 110 with the film deposited on the inner surface thereof appears in white, so that the contrast is reduced, and the susceptor mark 25 becomes hardly visible.

In the substrate position detecting apparatus 170 according to the present embodiment, the reflection restricting portion 133 is provided to prevent light irradiation onto the region where imaging targets are present such as the chamber mark 18 and the susceptor mark 25. That is, the substrate position detecting apparatus 170 according to the present embodiment is configured such that a portion of the reflection surface 131 is covered with a mask, and no reflection occurs in the portion.

As a result, a shadow is formed in the region where the imaging targets such as the chamber mark 18 and the susceptor mark 25 are present, and light is not reflected into the camera 140, so that an image may be captured at the natural luminance, acquiring an image with an appropriate contrast.

FIG. 3B is an enlarged view of a portion of the reflection surface 131. The region where the reflection restricting portion 133 is formed includes the region where the chamber mark 18 and the susceptor mark 25 are present. The reflective portion 132 of the reflection surface 131 may be made of various materials, which are capable of reflecting illumination light. The reflection restricting portion 133 may be made of various materials, which are capable of absorbing illumination light without reflecting the illumination light.

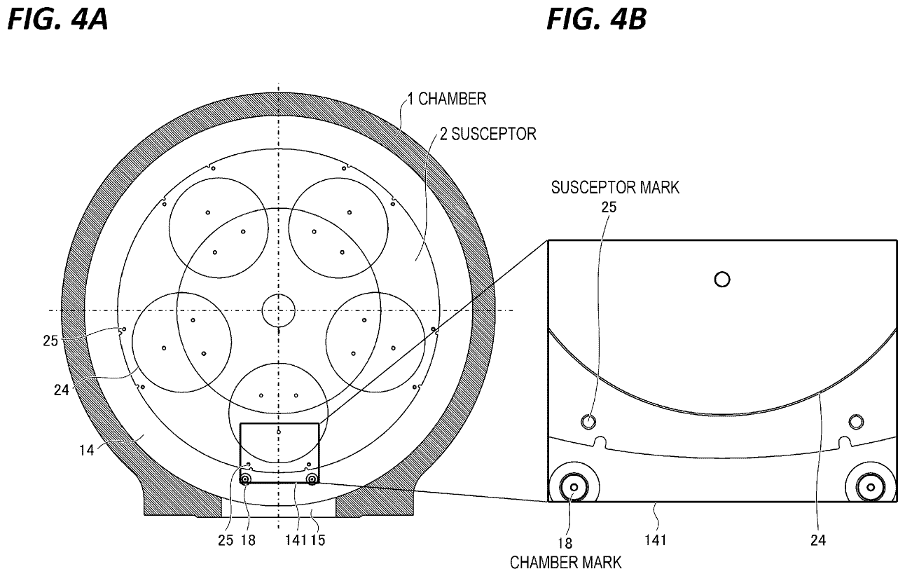

FIGS. 4A and 4B are views illustrating an example of the arrangement relationship between the chamber mark 18 and the susceptor mark 25 in the substrate processing apparatus 180 according to the present embodiment. FIG. 4A is an overall view illustrating the arrangement of the chamber mark 18 and the susceptor mark 25 in the chamber 1.

As illustrated in FIG. 4A, a plurality of substrates may be placed along the circumferential direction on the susceptor 2 accommodated in the chamber 1. In the example of the susceptor 2 of FIG. 4A, five substrates may be placed. Each substrate is placed in the recess 24 of the substrate placement region. Two susceptor marks 25 are formed corresponding to the recess 24 of each substrate placement region. Since the arrangement relationship between the recess 24 of the substrate placement region and the susceptor marks 25 is known in advance, the substrate position detecting apparatus 170 may detect the position of each substrate by detecting the susceptor marks 25.

The chamber mark 18 is provided on the surface of the bottom 14 of the chamber 1. Two chamber marks 18 are provided only at the location of a substrate carry-in/out port 15 of the chamber 1, and are configured such that the position of each substrate may be detected when the substrate is carried in/out. The chamber marks 18 and the susceptor marks 25 near the chamber marks 18 are included in a field of view range 141 of the camera 140.

FIG. 4B is an enlarged view illustrating the field of view range 141 of the camera 140 through the window 110. As illustrated in FIG. 4B, the chamber mark 18 provided in the chamber 1, the susceptor mark 25 provided on the susceptor 2, and the recess 24 of the substrate placement region are arranged close to each other. Since the chamber mark 18 and the susceptor mark 25 for the substrate position detection are positioned close to each other, the substrate position detecting apparatus 170 of the present embodiment may capture an image of the chamber mark 18 and the susceptor mark 25 using the single camera 140. The susceptor mark 25 may have any easily visible color, and may be formed in, for example, black.

Descriptions are made referring back to FIG. 1. The substrate processing apparatus 180 includes the flat chamber 1 that is substantially circular in planar view, and the susceptor 2 accommodated in the chamber 1. The susceptor 2 is provided in the chamber 1, and has a rotation center at the center of the chamber 1. The chamber 1 is configured such that the ceiling plate 11 may be separated from the container body 12. The ceiling plate 11 is pressed toward the side of the container body 12 through a sealing member (e.g., an O-ring 13) in the pressure-reduced state inside the chamber 1, to airtightly seal the chamber 1. Meanwhile, when the ceiling plate 11 needs to be separated from the container body 12, the ceiling plate 11 is lifted upward by a drive mechanism (not illustrated).

In the ceiling plate 11, the hole 16 is formed to provide an opening. On the upper surface of the ceiling plate 11, the window 110 is hermetically provided facing the hole 16. The substrate position detecting apparatus 170 described above is removably attached onto the window 110.

The susceptor 2 is fixed to a cylindrical core unit 21 at the center thereof. The core unit 21 is fixed to the upper end of the rotary shaft 22 extending vertically. The rotary shaft 22 penetrates the bottom 14 of the container body 12, and the lower end thereof is attached to a drive unit 23 that rotates the rotary shaft 22 around the vertical axis (e.g., in a clockwise direction). The rotary shaft 22 and the drive unit 23 are accommodated in a top-opened tubular case body 20.

The case body 20 is airtightly attached to the underside of the bottom 14 of the chamber 1 via a flange portion 20a provided on the upper surface thereof. Accordingly, the internal atmosphere of the case body 20 is isolated from the outside atmosphere thereof.

In the surface of the susceptor 2, circular recesses 24 are provided to place a plurality of wafers W therein along the rotational direction (circumferential direction). Each recess 24 has an inner diameter slightly larger (e.g., 4 mm) than the diameter of a wafer W and substantially the same depth as the thickness of the wafer W. The surface of the wafer W accommodated in the recess 24 is substantially flush with the surface of the susceptor 2 (the region on which no wafer W is placed). In the bottom surface of the recess 24, through holes (none of which are illustrated) are formed such that, for example, three lift pins (lifter pins) pass through the through holes to move a wafer W up and down while supporting the back surface of the wafer W.

Above the susceptor 2, a reaction gas nozzle and a separation gas nozzle are arranged while being spaced apart from each other in the circumferential direction of the chamber 1 (the rotational direction of the susceptor 2). Each of the reaction gas nozzle and the separation gas nozzle is attached to be introduced into the chamber 1 from the outer peripheral wall of the chamber 1 while fixing its gas introduction port, which is a base end, to the outer peripheral wall of the container body 12, and extends horizontally to the susceptor 2 along the radial direction of the container body 12. The reaction gas nozzle is connected to a gas supply source via, for example, a pipe and a flow rate controller. The separation gas nozzle is connected to a separation gas supply source via, for example, a pipe and a flow rate control valve.

In the reaction gas nozzle, a plurality of gas discharge holes opened toward the susceptor 2 is arranged at intervals of, for example, 10 mm along the length direction of the reaction gas nozzle. For example, as wafers W rotate and sequentially pass a processing region where a gas is being supplied, a film is deposited on the surface of the wafers W. At the same time, the film is deposited on the surface of the susceptor mark 25 as well.

Meanwhile, a protrusion portion 5 is provided in the lower surface of the ceiling plate 11 to surround the outer periphery of the core unit 21 fixing the susceptor 2. In the present embodiment, the protrusion portion 5 is continuous with the portion of a convex portion 4 on the side of the rotation center. A ceiling surface 45 is provided on the lower surface of the ceiling plate 11. The inner peripheral wall of the container body 12 is recessed outwardly over the section from the portion facing the outer end surface of the susceptor 2 to the bottom 14. The recessed portion has a substantially rectangular cross-sectional shape, and is an exhaust region. At the bottom of each exhaust region, an exhaust port 61 is formed. The exhaust port 61 is connected to, for example, a vacuum pump 64, which is a vacuum exhaust means, via an exhaust pipe 63 and a pressure controller 65.

In the space between the susceptor 2 and the bottom 14 of the chamber 1, a heater unit 7 is provided as a heating means. The heater unit 7 heats the wafers W on the susceptor 2 to a temperature determined by a process recipe (e.g., 400° C.).

A ring-shaped cover member 71 is provided below the vicinity of the periphery of the susceptor 2, to partition the atmosphere from the space above the susceptor 2 to the exhaust region and the atmosphere where the heater unit 7 is disposed, thereby suppressing the intrusion of a gas into the space below the susceptor 2. In the case body 20, a purge gas supply pipe 72 is provided to supply a purge gas into a narrow space for performing a purging. In the bottom 14 of the chamber 1, a plurality of purge gas supply pipes 73 is provided at predetermined angular intervals in the circumferential direction below the heater unit 7, to purge the space where the heater unit 7 is disposed.

A separation gas supply pipe 51 is connected to the center of the ceiling plate 11 of the chamber 1, to supply a separation gas into the space between the ceiling plate 11 and the core unit 21. The separation gas supplied into the space is discharged along the surface of the wafer placement region of the susceptor 2 toward the circumferential edge of the susceptor 2 through a narrow gap 50 between the protrusion portion 5 and the susceptor 2. The gap 50 is maintained at a higher pressure than that in the processing region, to suppress the gas supplied into the processing region from being mixed with the separation gas through the central region C.

In the side wall of the chamber 1, a transfer port is formed to transfer a wafer W, which is a substrate, between an external transfer arm and the susceptor 2. The transfer port is opened and closed by a gate valve. Since a wafer W in the recess 24 of the susceptor 2 is transferred from/to the transfer arm at a transfer position directed toward the transfer port, transfer lift pins and a lift mechanism thereof are provided at the portion corresponding to the transfer position below the susceptor 2 to penetrate the recess 24 thereby lifting the wafer W from the back surface thereof.

The substrate processing apparatus 180 according to the present embodiment includes a control unit 100 configured with a computer for controlling the operation of the entire apparatus. A memory of the control unit 100 stores a program for causing the substrate processing apparatus 180 to perform a substrate processing according to the control of the control unit 100. The program is stored on a medium such as a hard disk, a compact disk, a magneto-optical disk, a memory card, or a flexible disk, and is read by a predetermined reader to be installed in the control unit 100.

While FIG. 1 illustrates an example where the control unit 100 and the processing unit 160 are configured separately, the control unit 100 and the processing unit 160 may be provided in an integrated form. When the control unit 100 and the processing unit 160 are configured separately, the processes of the control unit 100 and the processing unit 160 may be performed by being distributed between the control unit 100 and the processing unit 160. The substrate position detecting apparatus 170 according to the present embodiment may be provided as a camera unit including the light 120, the light reflector 130, the camera 140, the housing 150, and the processing unit 160.

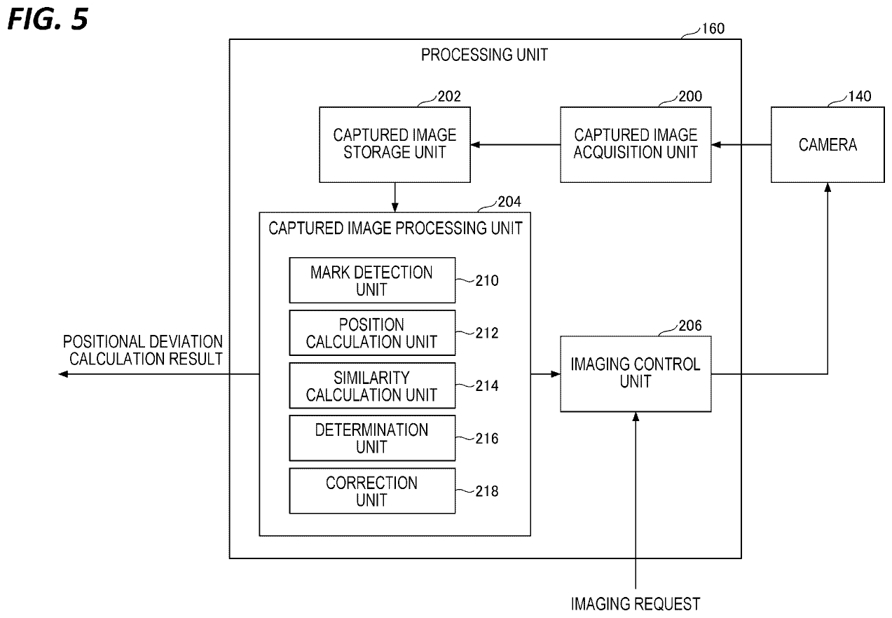

The processing unit 160 of the substrate processing apparatus 180 according to the present embodiment is implemented with, for example, the functional blocks illustrated in FIG. 5. FIG. 5 is a functional block diagram of an example of the processing unit 160 according to the present embodiment. The functional block diagram of FIG. 5 omits the illustration of components unnecessary for describing the present embodiment.

The processing unit 160 of FIG. 5 executes a program to implement a captured image acquisition unit 200, a captured image storage unit 202, a captured image processing unit 204, and an imaging control unit 206.

The captured image acquisition unit 200 acquires an image of the interior of the chamber 1 that is captured by the camera 140 through the window 110 (hereinafter, referred to as a captured image of the camera 140). The captured image of the camera 140 acquired by the captured image acquisition unit 200 is stored in the captured image storage unit 202. The captured image storage unit 202 stores, for example, the captured image of the camera 140 before a deposition (e.g., the earliest in time) as an original captured image (hereinafter, referred to as a reference image).

Based on the captured image of the camera 140 stored by the captured image storage unit 202, the captured image processing unit 204 performs calculation processes to detect the positions of the chamber mark 18 and the susceptor mark 25 used for positioning the susceptor 2.

A mark detection unit 210 detects the region of the chamber mark 18 and the susceptor mark 25 from the captured image of the camera 140. A position calculation unit 212 performs calculations on the positions of the chamber mark 18 and the susceptor mark 25, from the region of the chamber mark 18 and the susceptor mark 25 detected by the mark detection unit 210 from the captured image of the camera 140. For example, the position calculation unit 212 performs a calculation on the position of the chamber mark 18 (reference position). Further, the position calculation unit 212 performs a calculation on the position of the susceptor mark 25. Further, the position calculation unit 212 performs a calculation on a positional deviation of the susceptor 2 used for positioning the susceptor 2.

A similarity calculation unit 214 calculates a similarity between the image of the susceptor mark 25 included in the current captured image of the camera 140 (hereinafter, referred to as the current image) and the image of the susceptor mark 25 included in the reference image of the camera 140. The index of the structural similarity (hereinafter, referred to as SSIM) may be used for measuring the similarity between the image of the susceptor mark 25 included in the current image of the camera 140 and the image of the susceptor mark 25 included in the reference image of the camera 140.

An SSIM value is an existing index that evaluates image quality in terms of luminance, contrast, and structure. The processing unit 160 according to the present embodiment uses the SSIM value as the index of similarity between the image of the susceptor mark 25 included in the current image of the camera 140 and the image of the susceptor mark 25 included in the reference image of the camera 140. The SSIM value ranges from “0” to “1.” The SSIM value approaches “1” as the similarity increases between the image of the susceptor mark 25 included in the current image of the camera 140 and the image of the susceptor mark 25 included in the reference image of the camera 140. Further, the SSIM value approaches “0” as the similarity decreases between the image of the susceptor mark 25 included in the current image of the camera 140 and the image of the susceptor mark 25 included in the reference image of the camera 140. For example, the SSIM value tends to decrease as a film is accumulated by the repetition of the substrate processing in the substrate processing apparatus 180, and increase when the accumulated film is removed by a cleaning of the susceptor 2.

Based on the similarity calculated by the similarity calculation unit 214 between the image of the susceptor mark 25 included in the current image of the camera 140 and the image of the susceptor mark 25 included in the reference image of the camera 140, a determination unit 216 determines the deterioration of the image of the susceptor mark 25 included in the current image of the camera 140 (contrast decrease).

For example, when the SSIM value decreases to a threshold or lower, the determination unit 216 determines that the image of the susceptor mark 25 included in the current image of the camera 140 has deteriorated. When the SSIM value does not decrease the threshold or lower, the determination unit 216 determines that the image of the susceptor mark 25 included in the current image of the camera 140 has not deteriorated.

Based on the deterioration of the image of the susceptor mark 25 included in the current image of the camera 140, a correction unit 218 performs a correction process to improve the precision for the detection of the region of the susceptor mark 25 by the mark detection unit 210.

When it is determined that the image of the susceptor mark 25 included in the current image of the camera 140 has deteriorated, the correction unit 218 enhances the contrast of the image of the susceptor mark 25 included in the current image, through a histogram equalization process or an adaptive histogram equalization process. By enhancing the contrast of the image of the susceptor mark 25 included in the current image through the histogram equalization process or the adaptive histogram equalization process, the correction unit 218 performs the correction process for improving the precision of the detection of the susceptor mark 25 from the captured image of the camera 140.

The correction unit 218 adjusts the shutter speed of the camera 140 according to a previously calculated SSIM value, to enhance the contrast of the image of the susceptor mark 25 included in the current image. By adjusting the shutter speed of the camera 140 according to the previously calculated SSIM value to enhance the contrast of the image of the susceptor mark 25 included in the current image, the correction unit 218 performs the correction process for improving the precision of the detection of the susceptor mark 25 from the captured image of the camera 140.

The correction unit 218 adjusts a binarization threshold used for the detection of the susceptor mark 25 by the mark detection unit 210, according to a previously calculated SSIM value. By adjusting the binarization threshold used for the detection of the susceptor mark 25 by the mark detection unit 210 according to the previously calculated SSIM value, the correction unit 218 performs the correction process for improving the precision of the detection of the susceptor mark 25 from the captured image of the camera 140. By improving the precision of the detection of the susceptor mark 25 from the captured image of the camera 140, the correction unit 218 may detect the susceptor mark 25 from the captured image that has deteriorated. As a result, in the present embodiment, the cleaning frequency is reduced, so that it is possible to achieve the productivity improvement resulting from the reduction of downtime of the substrate processing apparatus 180, the reduction of recovery man-hours of the substrate processing apparatus 180, and the reduction of replacement costs of the susceptor 2 or the susceptor mark 25.

The captured image processing unit 204 transmits information on, for example, the calculation result of the positional deviation used for positioning the susceptor 2 to the control unit 100, to cause the control unit 100 to adjust the position of the susceptor 2. Further, the captured image processing unit 204 transmits information on, for example, the shutter speed necessary for controlling the camera 140 to the imaging control unit 206, to cause the imaging control unit 206 to control the imaging by the camera 140.

The imaging control unit 206 controls the imaging by the camera 140 according to, for example, an imaging request received from the control unit 100 and information necessary for controlling the camera 140 received from the captured image processing unit 204.

The correction unit 218 performs the histogram equalization process or the adaptive histogram equalization process as described herein below, to enhance the contrast of the image of the susceptor mark 25 included in the captured image of the camera 140.

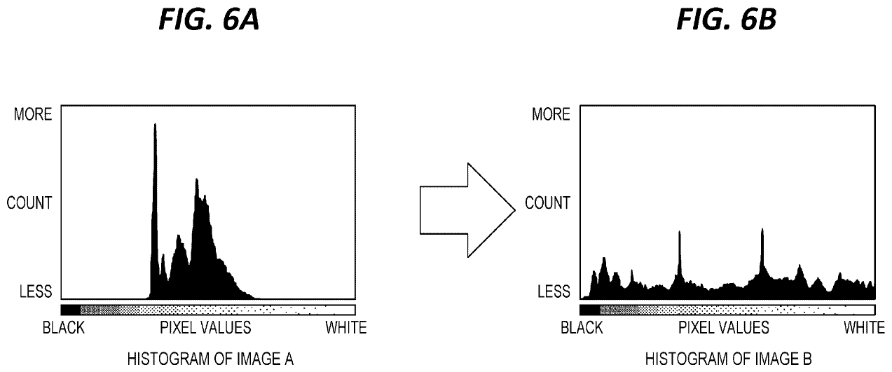

FIGS. 6A and 6B are views illustrating the histogram equalization. FIG. 6A illustrates a histogram of pixel values of an image A with a low contrast. FIG. 6B illustrates a histogram of pixel values of an image B with a high contrast. As illustrated in FIG. 6A, the histogram of the image A with the low contrast represents the pixel values clustered in a narrow range. Meanwhile, as illustrated in FIG. 6B, the histogram of the image B with the high contrast represents the pixel values spread over a wide range.

The histogram equalization is a type of algorithm that corrects a deteriorated image. The histogram equalization process or the adaptive histogram equalization process is a process to perform a concentration transformation such that the histogram of pixel values is distributed across a wide range (flattened overall). The image A with the low contrast in FIG. 6A is adjusted so that the peak areas are flattened overall, and therefore, becomes the image with the enhanced high contrast as illustrated in FIG. 6B.

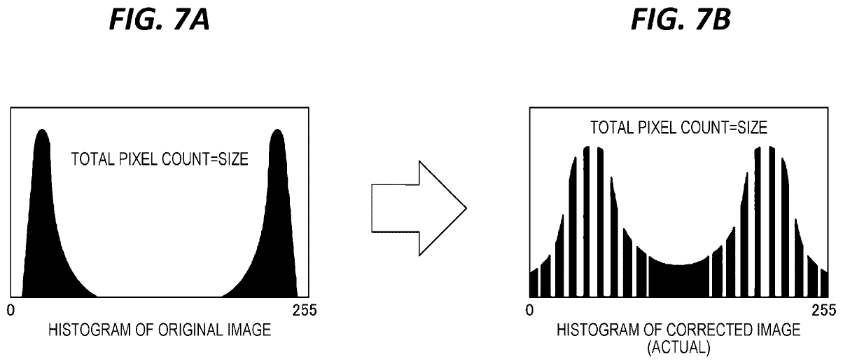

FIGS. 7A and 7B are views illustrating the histogram equalization for an image in which light and dark parts are clearly present. In the original image of FIG. 7A where light and dark parts are clearly present, the level with the high frequency may be divided into multiple fine levels, for example, as illustrated in FIG. 7B, so that the histogram of pixel values is adjusted to spread across a wide range.

The correction unit 218 may perform the adaptive histogram equalization process, which is an improvement of the general histogram equalization process. The adaptive histogram equalization process improves the general histogram equalization process that flattens the histogram of an entire image, to perform the histogram equalization for each local region. The adaptive histogram equalization process may perform a contrast adjustment suitable for each small region of an image.

For example, the general histogram equalization process performs a uniform processing on an entire image. The adaptive histogram equalization process divides an image into small regions, and performs a local histogram equalization for each small region. Thus, in the adaptive histogram equalization process, an overexposure or an underexposure of the entire image does not easily occur. Therefore, the adaptive histogram equalization process is suitable for an extremely underexposed image such as the deteriorated image of the susceptor mark 25.

The adaptive histogram equalization process has a parameter called “contrast limit.” With this parameter, the adaptive histogram equalization process limits an excessive contrast adjustment for each local region. By limiting the contrast adjustment, the adaptive histogram equalization process may suppress the increase of noise or the deterioration of an image. In the general histogram equalization process, the excessive contrast adjustment and the underexposure may occur, which prevents the improvement of an image. The adaptive histogram equalization process may limit the contrast adjustment, and therefore, may eliminate the problem of the general histogram equalization process.

Further, the adaptive histogram equalization process divides an image into small tiles (blocks). By selecting the size of blocks, the adaptive histogram equalization process may adjust the effect of local processing and the speed of processing. The adaptive histogram equalization process is useful when a local feature of an image is important, and also useful for detecting the image of the susceptor mark 25 from the captured image of the camera 140.

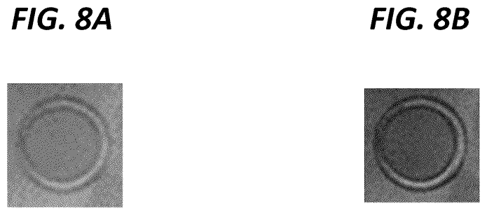

FIGS. 8A and 8B are views illustrating an example of the image of the susceptor mark 25 subjected to the general histogram equalization process or the adaptive histogram equalization process. FIG. 8A is an example of the image of the susceptor mark 25 subjected to the general histogram equalization process. In FIG. 8A, since the entire image is uniformly processed, the image has a slightly whitish tone, and includes a distorted part, for example, at the edge.

FIG. 8B is an example of the image of the susceptor mark 25 subjected to the adaptive histogram equalization process. In FIG. 8B, the parameters such as the contrast limit and the block size are adjusted, to implement the contrast adjustment and the local optimization.

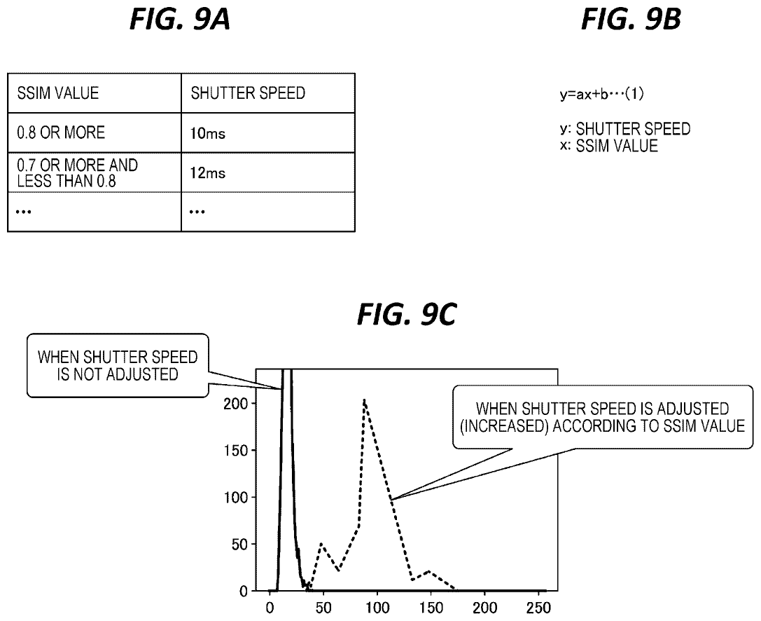

FIGS. 9A to 9C are views illustrating the process of adjusting the shutter speed of the camera 140 according to the SSIM value. FIG. 9A is an example of a table in which the SSIM value and the shutter speed are associated with each other. FIG. 9B is an example of an equation to which the SSIM value and the shutter speed are applied. The SSIM value and the shutter speed illustrated in FIGS. 9A and 9B are associated in advance through a preliminary evaluation. In FIGS. 9A and 9B, the SSIM value and the shutter speed are associated such that the shutter speed increases as the SSIM value decreases.

FIG. 9C illustrates the histogram of pixel values of the image in a case where the shutter speed is not adjusted according to the SSIM value, and the histogram of pixel values of the image in a case where the shutter speed is adjusted (increased) according to the SSIM value. As illustrated in FIG. 9C, by increasing the shutter speed when the SSIM value decreases, the contrast of the captured image of the camera 140 may be enhanced.

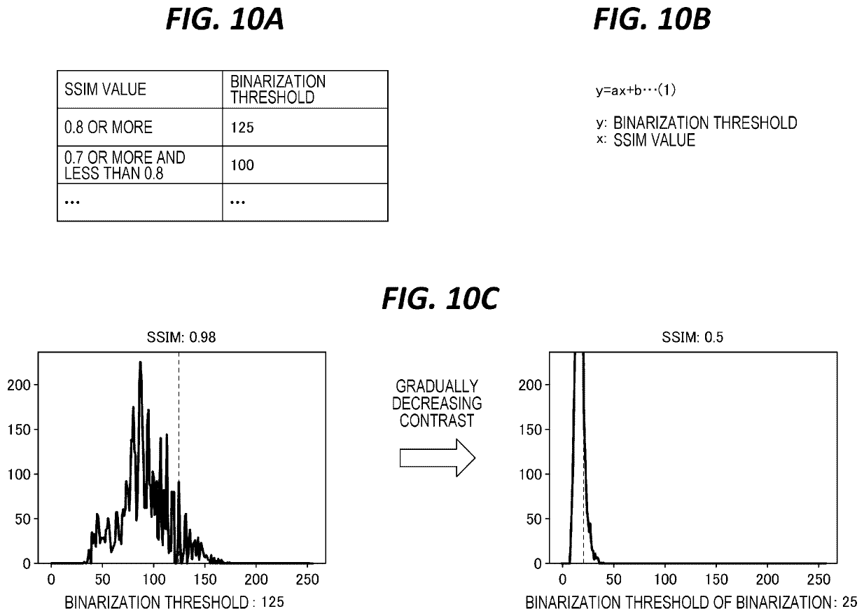

FIGS. 10A to 10C are views illustrating the process of adjusting the binarization threshold used for the detection of the susceptor mark 25 according to the SSIM value. FIG. 10A is an example of a table in which the SSIM value and the binarization threshold are associated with each other. FIG. 10B is an example of an equation to which the SSIM value and the binarization threshold are applied.

The SSIM value and the binarization threshold illustrated in FIGS. 10A and 10B are associated in advance through a preliminary evaluation. In FIGS. 10A and 10B, the SSIM value and the binarization threshold are associated such that the binarization threshold decreases as the SSIM value decreases.

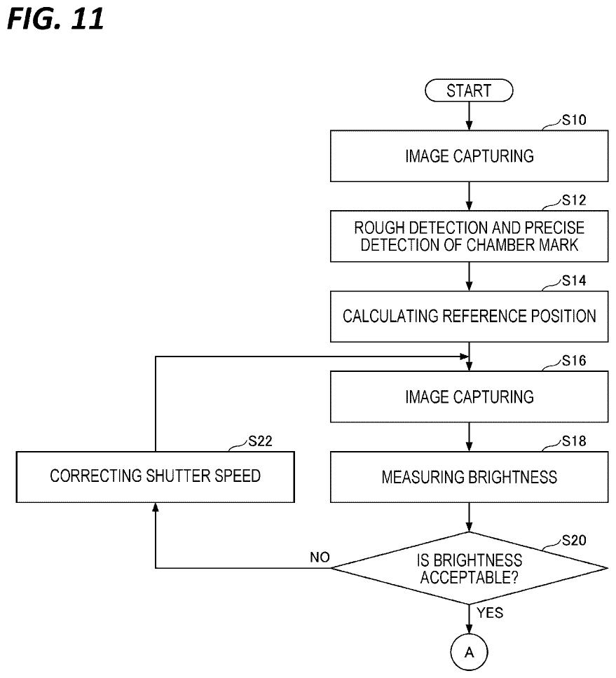

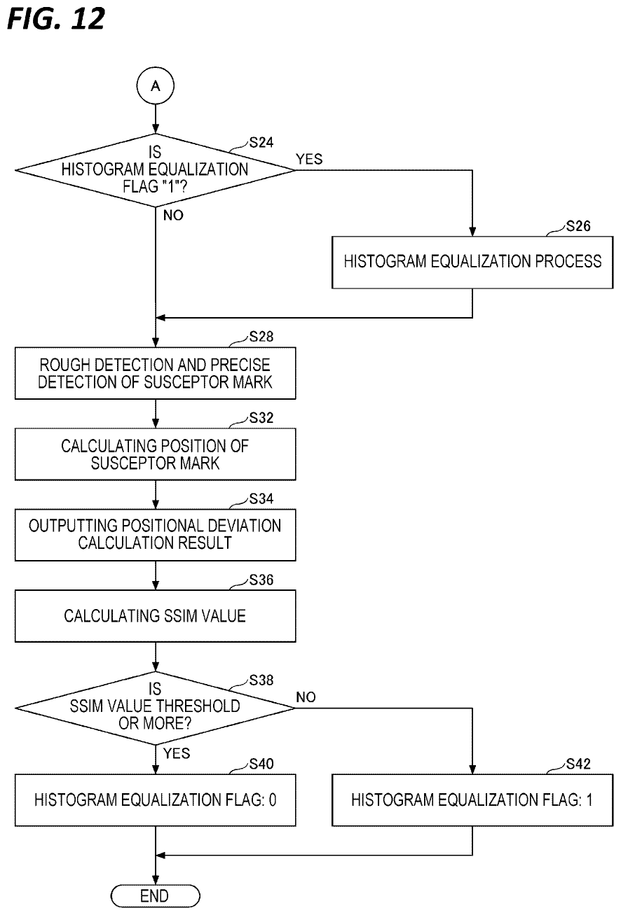

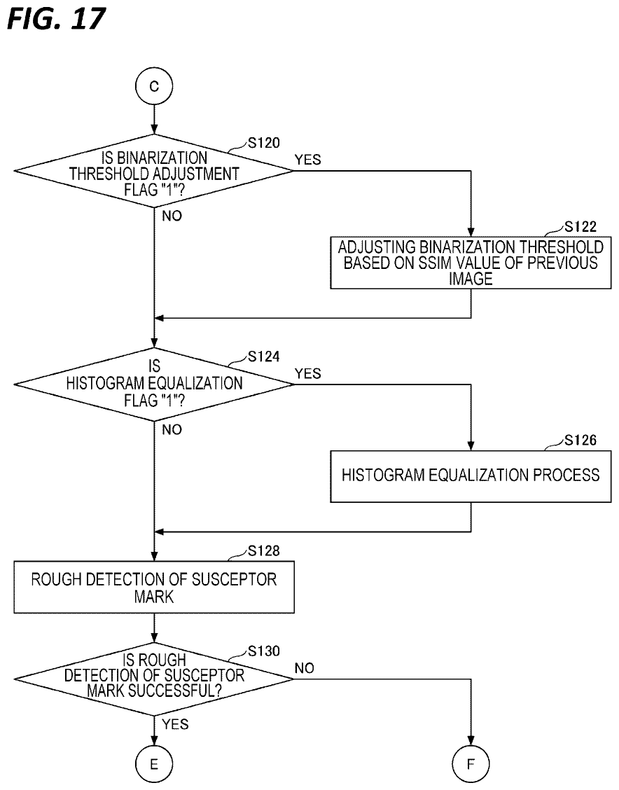

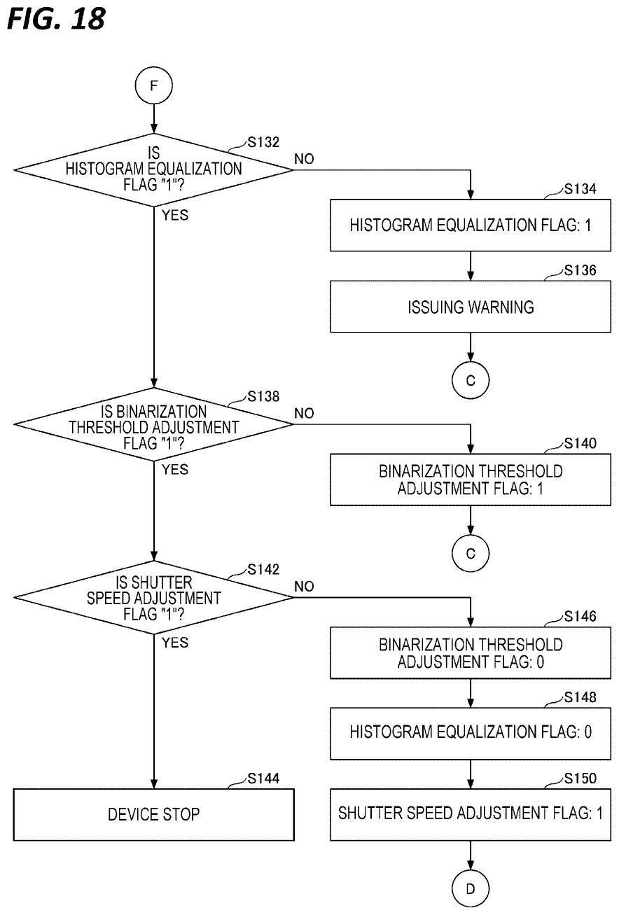

FIG. 10C illustrates the binarization threshold adjusted according to the SSIM value. As illustrated in FIG. 10C, when the SSIM value decreases due to contrast degradation, the histogram of pixel values is biased toward the pixel value “0.” Therefore, as illustrated in FIG. 10C, the binarization threshold is adjusted to approach the pixel value “0” when the SSIM value decreases, so that the precision for the detection of the susceptor mark 25 from the captured image of the camera 140 may be improved. Hereinafter, the process procedure performed by the substrate position detecting apparatus 170 according to the present embodiment will be described using FIGS. 11 to 19. FIGS. 11 and 12 are flowcharts illustrating an example of the process procedure of the substrate position detecting apparatus 170 according to the present embodiment.

In step S10, the camera 140 captures an image of the interior of the chamber 1 through the window 110 according to the control of the imaging control unit 206 of the processing unit 160. The captured image acquisition unit 200 of the processing unit 160 stores the captured image of the camera 140 in the captured image storage unit 202.

In step S12, the mark detection unit 210 performs a rough detection and a precise detection of the chamber mark 18. The rough detection of the chamber mark 18 is an image processing that roughly detects the region of the chamber mark 18 from the captured image of the camera 140. The precise detection of the chamber mark 18 is an image processing that precisely detects the region of the chamber mark 18. In step S14, the position calculation unit 212 performs a calculation on the position of the chamber mark 18 (reference position) from the region of the chamber mark 18 detected in step S12.

In step S16, the camera 140 captures an image of the interior of the chamber 1 through the window 110 according to the control of the imaging control unit 206 for the measurement of brightness in step S18. In step S18, the captured image processing unit 204 measures the brightness of the captured image of the camera 140 obtained in step S16.

In step S20, the determination unit 216 determines whether the brightness of the captured image measured in step S18 is acceptable. When it is determined that the brightness of the captured image measured in step S18 is not acceptable, the correction unit 218 adjusts the shutter speed of the camera 140 in step S22. The captured image processing unit 204 repeats steps S16 to S22 until the brightness of the captured image of the camera 140 obtained in step S16 is determined to be acceptable. When it is determined that the brightness of the captured image measured in step S18 is acceptable, the captured image processing unit 204 proceeds to step S24.

In step S24, the correction unit 218 determines whether a histogram equalization flag is “1.” The histogram equalization flag is information indicating whether the histogram equalization process is needed. The histogram equalization flag “1” indicates a state where the histogram equalization process is needed. The histogram equalization flag “0” indicates a state where the histogram equalization process is not needed. When the histogram equalization flag is “1,” the correction unit 218 performs the adaptive histogram equalization process in step S26, to enhance the contrast of the image of the susceptor mark 25 included in the current image. When the histogram equalization flag is “0,” the correction unit 218 skips step S26.

In step S28, the mark detection unit 210 performs a rough detection and a precise detection of the susceptor mark 25. The rough detection of the susceptor mark 25 is an image processing that roughly detects the region of the susceptor mark 25 from the captured image of the camera 140. The precise detection of the susceptor mark 25 is an image processing that precisely detects the region of the susceptor mark 25.

In step S32, the position calculation unit 212 performs a calculation on the position of the susceptor mark 25 from the region of the susceptor mark 25 detected by the mark detection unit 210 from the captured image of the camera 140. In step S34, the position calculation unit 212 performs a calculation on a positional deviation of the susceptor 2 used for positioning the susceptor 2.

In step S36, the similarity calculation unit 214 calculates the SSIM value as an example of the index of similarity between the image of the susceptor mark 25 included in the current image of the camera 140 and the image of the susceptor mark 25 included in the reference image of the camera 140.

In step S38, the determination unit 216 determines whether the SSIM value calculated by the similarity calculation unit 214 is a threshold or more. When it is determined that the SSIM value is the threshold or more, the determination unit 216 determines that the image of the susceptor mark 25 included in the current image of the camera 140 has not deteriorated, and proceeds to step S40. In step S40, the determination unit 216 sets “0” for the histogram equalization flag to indicate the state where the histogram equalization process is not needed.

When it is determined that the SSIM value is not the threshold or more, the determination unit 216 determines that the image of the susceptor mark 25 included in the current image of the camera 140 has deteriorated, and proceeds to step S42. In step S42, the determination unit 216 sets “1” for the histogram equalization flag to indicate the state where the histogram equalization process is needed.

According to the process of the flowcharts illustrated in FIGS. 11 and 12, the deterioration of the image of the susceptor mark 25 included in the current image of the camera 140 may be determined based on the SSIM value for the image of the susceptor mark 25 included in the current image of the camera 140 and the image of the susceptor mark 25 included in the reference image. When the image of the susceptor mark 25 included in the current image deteriorates, the adaptive histogram equalization process is performed for the next current image of the camera 140 to enhance the contrast of the image of the susceptor mark 25 included in the next current image, so that the precision for the detection of the region of the susceptor mark 25 may be improved.

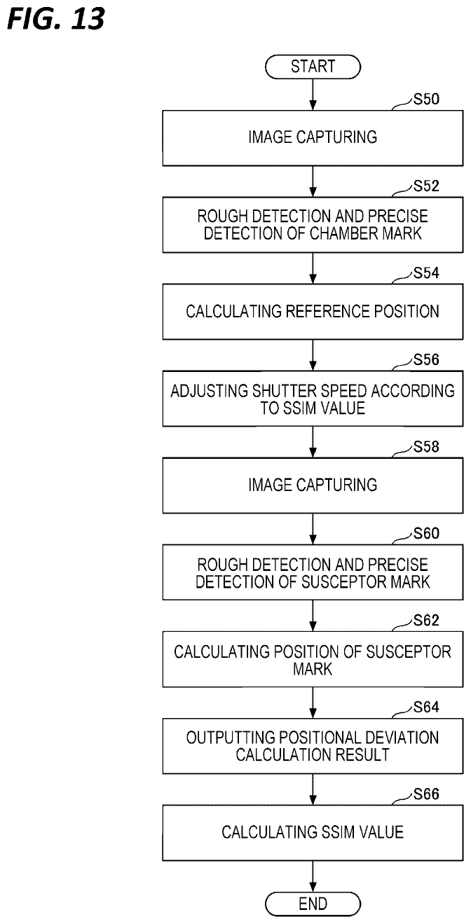

In the process of the flowcharts illustrated in FIGS. 11 and 12, the adaptive histogram equalization process is performed as the correction process to improve the precision for the detection of the region of the susceptor mark 25 by the mark detection unit 210. The correction process to improve the precision for the detection of the region of the susceptor mark 25 by the mark detection unit 210 may be performed, for example, as illustrated in FIG. 13. FIG. 13 is a flowchart illustrating an example of the process procedure performed by the substrate position detecting apparatus 170 according to the present embodiment.

In step S50, the camera 140 captures an image of the interior of the chamber 1 through the window 110 according to the control of the imaging control unit 206 of the processing unit 160. The captured image acquisition unit 200 of the processing unit 160 stores the captured image of the camera 140 in the captured image storage unit 202.

In step S52, the mark detection unit 210 performs a rough detection and a precise detection of the chamber mark 18. In step S54, the position calculation unit 212 performs a calculation on the reference position of the chamber mark 18 from the region of the chamber mark 18 detected in step S52.

In step S56, the correction unit 218 adjusts the shutter speed of the camera 140 according to the SSIM value calculated in S66 of the previous process. The process of adjusting the shutter speed of the camera 140 according to the SSIM value in step S56 is a process of increasing the shutter speed when the SSIM value decreases to enhance the contrast of the captured image of the camera 140. In step S58, the camera 140 captures an image of the interior of the chamber 1 through the window 110 at the shutter speed adjusted in step S56. The captured image acquisition unit 200 stores the captured image of the camera 140 in the captured image storage unit 202.

In step S60, the mark detection unit 210 performs a rough detection and a precise detection of the susceptor mark 25. In step S62, the position calculation unit 212 performs a calculation on the position of the susceptor mark 25, from the region of the susceptor mark 25 detected by the mark detection unit 210 from the captured image of the camera 140. In step S64, the position calculation unit 212 performs a calculation on a positional deviation of the susceptor 2 used for positioning the susceptor 2.

In step S66, the similarity calculation unit 214 calculates the SSIM value as an example of the index of similarity between the image of the susceptor mark 25 included in the current image of the camera 140 and the image of the susceptor mark 25 included in the reference image of the camera 140.

According to the process of the flowchart illustrated in FIG. 13, when the image of the susceptor mark 25 included in the current image deteriorates, the shutter speed is adjusted for the next captured image of the camera 140 to enhance the contrast of the image of the susceptor mark 25, so that the precision for the detection of the region of the susceptor mark 25 may be improved.

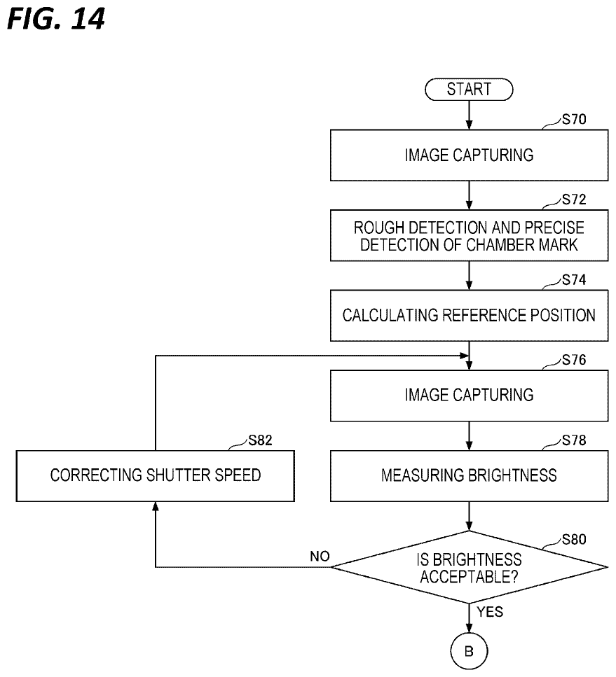

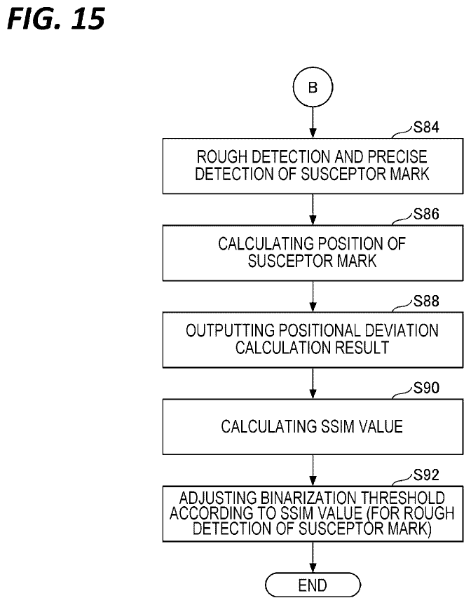

The correction process to improve the precision for the detection of the region of the susceptor mark 25 by the mark detection unit 210 may be performed, for example, as illustrated in FIGS. 14 and 15. FIGS. 14 and 15 are flowcharts illustrating an example of the process procedure performed by the substrate position detecting apparatus 170 according to the present embodiment.

Since steps S70 to S80 are the same as steps S10 to S20 in FIG. 11, descriptions thereof will be omitted. In step S84, the mark detection unit 210 performs a rough detection and a precise detection of the susceptor mark 25. The mark detection unit 210 uses the binarization threshold for the detection of the susceptor mark 25. The binarization threshold used in step S84 is adjusted according to the SSIM value in step S92 of the previous process, to improve the precision for the detection of the susceptor mark 25 from the captured image of the camera 140.

In step S86, the position calculation unit 212 performs a calculation on the position of the susceptor mark 25, from the region of the susceptor mark 25 detected by the mark detection unit 210 from the captured image of the camera 140. In step S88, the position calculation unit 212 performs a calculation on a positional deviation of the susceptor 2 used for positioning the susceptor 2.

In step S90, the similarity calculation unit 214 calculates the SSIM value as an example of the index of similarity between the image of the susceptor mark 25 included in the current image of the camera 140 and the image of the susceptor mark 25 included in the reference image of the camera 140.

In step S92, the correction unit 218 adjusts the binarization threshold used when the mark detection unit 210 detects the susceptor mark 25, according to the SSIM value calculated in step S90. The correction unit 218 adjusts the binarization threshold used when the mark detection unit 210 detects the susceptor mark 25, to approach the pixel value “0” when the SSIM value decreases, so that the precision for the detection of the susceptor mark 25 from the captured image of the camera 140 may be improved.

According to the process of the flowcharts illustrated in FIGS. 14 and 15, the deterioration of the image of the susceptor mark 25 included in the current image of the camera 140 may be determined based on the SSIM value for the image of the susceptor mark 25 included in the current image of the camera 140 and the image of the susceptor mark 25 included in the reference image.

When the image of the susceptor mark 25 included in the current image deteriorates, the binarization threshold used for the detection of the susceptor mark 2 is adjusted to enhance the contrast of the image of the susceptor mark 25 included in the next current image, so that the precision for the detection of the region of the susceptor mark 25 may be improved.

The processes to improve the precision for the detection of the susceptor mark 25 illustrated in FIGS. 11 to 15 may be performed in combination. Here, descriptions have been made on the combination of the adaptive histogram equalization process, the shutter speed adjustment process, and the binarization threshold adjustment process. However, two of the adaptive histogram equalization process, the shutter speed adjustment process, and the binarization threshold adjustment process may be combined.

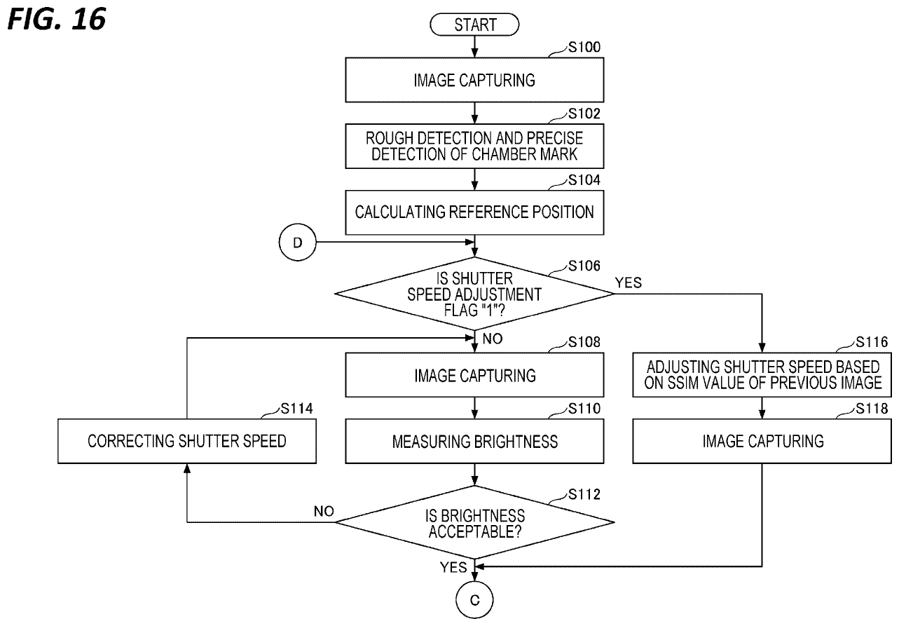

FIGS. 16 to 19 are flowcharts illustrating an example of the process procedure performed by the substrate position detecting apparatus 170 according to the present embodiment. Since the processes illustrated in FIGS. 16 to 19 are partially identical to those illustrated in FIGS. 11 to 15, descriptions thereof will be omitted as appropriate.

Since steps S100 to S104 are the same as steps S10 to S14, descriptions thereof will be omitted. In step S106, the correction unit 218 determines whether a shutter speed adjustment flag is “1.”

The shutter speed adjustment flag “1” indicates a state where the shutter speed adjustment process is needed. The shutter speed adjustment flag “0” indicates a state where the shutter speed adjustment process is not needed.

When it is determined that the shutter speed adjustment flag is “1,” the correction unit 218 proceeds to step S116 to adjust the shutter speed of the camera 140 according to the SSIM value calculated in step S158 of the previous process. As a result, the contrast of the captured image in step S118 may be enhanced. In step S118, the camera 140 captures an image of the interior of the chamber 1 through the window 110 at the shutter speed adjusted in step S116, and proceeds to step S120. The captured image acquisition unit 200 stores the captured image of the camera 140 in the captured image storage unit 202.

When it is determined that the shutter speed adjustment flag is not “1,” the process proceeds to step S108, and the camera 140 captures an image of the interior of the chamber 1 through the window 110 according to the control of the imaging control unit 206 for the measurement of the brightness in step S110. In step S110, the captured image processing unit 204 measures the brightness of the captured image of the camera 140 obtained in step S108.

In step S112, the determination unit 216 determines whether the brightness of the captured image measured in step S110 is acceptable. When it is determined that the brightness of the captured image measured in step S110 is not acceptable, the correction unit 218 adjusts the shutter speed of the camera 140 in step S114, as in step S22 of FIG. 11. The captured image processing unit 204 repeats steps $108 to S114 until the brightness of the captured image of the camera 140 obtained in step S108 is determined to be acceptable. When it is determined that the brightness of the captured image measured in step S110 is acceptable, the captured image processing unit 204 proceeds to step S120.

In step S120, the correction unit 218 determines whether a binarization threshold adjustment flag is “1.” The binarization threshold adjustment flag “1” indicates a state where the binarization threshold adjustment process is needed. The binarization threshold adjustment flag “O” indicates a state where the binarization threshold adjustment process is not needed.

When it is determined that the binarization threshold adjustment flag is “1,” the correction unit 218 proceeds to step S122 to adjust the binarization threshold used when the mark detection unit 210 detects the susceptor mark 25, according to the SSIM value calculated in step S158 of the previous process. When it is determined that the binarization threshold adjustment flag is not “1,” the correction unit 218 skips step S122.

In step S124, the correction unit 218 determines whether the histogram equalization flag is “1.” When it is determined that the histogram equalization flag is “1,” the correction unit 218 performs the adaptive histogram equalization process in step S126, to enhance the contrast of the image of the susceptor mark 25 in the current image. When the histogram equalization flag is “0,” the correction unit 218 skips step S126.

The process proceeds to step S128, and the mark detection unit 210 performs a rough detection of the susceptor mark 25. The captured image of the camera 140 subjected to the rough detection of the susceptor mark 25 in step S128 is the captured image with the contrast enhanced by the shutter speed adjustment according to the shutter speed adjustment flag, the binarization threshold adjustment according to the binarization threshold adjustment flag, and the adaptive histogram equalization process according to the histogram equalization flag.

In step S130, the mark detection unit 210 determines whether the rough detection of the susceptor mark 25 is successful. When it is determined that the rough detection of the susceptor mark 25 is successful, the mark detection unit 210 proceeds to step S152. Meanwhile, when it is determined that the rough detection of the susceptor mark 25 is not successful, the determination unit 216 proceeds to step S132.

In step S132, the determination unit 216 determines whether the histogram equalization flag is “1.” When it is determined that the histogram equalization flag is not “1,” the process proceeds to step S134, and the determination unit 216 sets “1” for the histogram equalization flag.

In step S136, the determination unit 216 issues WARNING to a user such as an operator, and then, the process returns to step S120. The issuance may be performed step by step such as WARNING and ALARM. For example, when the detection of the susceptor mark 25 fails, the position of the susceptor 2 may not be adjusted, and as a result, a stop may occur during the substrate processing (during Run). The stop during the substrate processing (during Run) causes the downtime for a recovery work. Further, when the precision for the detection of the susceptor mark 25 is low, the susceptor 2 or the lift pins may be damaged. For example, when WARNING is issued before the stop occurs during the substrate processing (during Run), the user such as the operator may perform a cleaning as planned before the stop occurs during the Run so that, for example, disposal of wafers W due to the sudden stop during the substrate processing may be prevented.

When it is determined that the histogram equalization flag is “1,” the process proceeds to step S138, and the determination unit 216 determines whether the binarization threshold adjustment flag is “1.” When it is determined that the binarization threshold adjustment flag is not “1,” the process proceeds to step S140, and the determination unit 216 sets “1” for the binarization threshold adjustment flag, then, the process returns to step S120. After step S140, the determination unit 216 may perform the same issuance as that in step S136.

When it is determined that the binarization threshold adjustment flag is “1,” the process proceeds to step S142, and the determination unit 216 determines whether the shutter speed adjustment flag is “1.” When it is determined that the shutter speed adjustment flag is “1,” the determination unit 216 proceeds to step S144 to stop the substrate processing apparatus 180, since there is no process left to enhance the contrast of the image of the susceptor mark 25.

When it is determined that the shutter speed adjustment flag is not “1,” the process proceeds to step S146, and the determination unit 216 sets “0” for the binarization threshold adjustment flag. In step S148, the determination unit 216 sets “0” for the histogram equalization flag. Further, in step S150, the determination unit 216 sets “1” for the shutter speed adjustment flag. After step S150, the correction unit 218 returns to step S106.

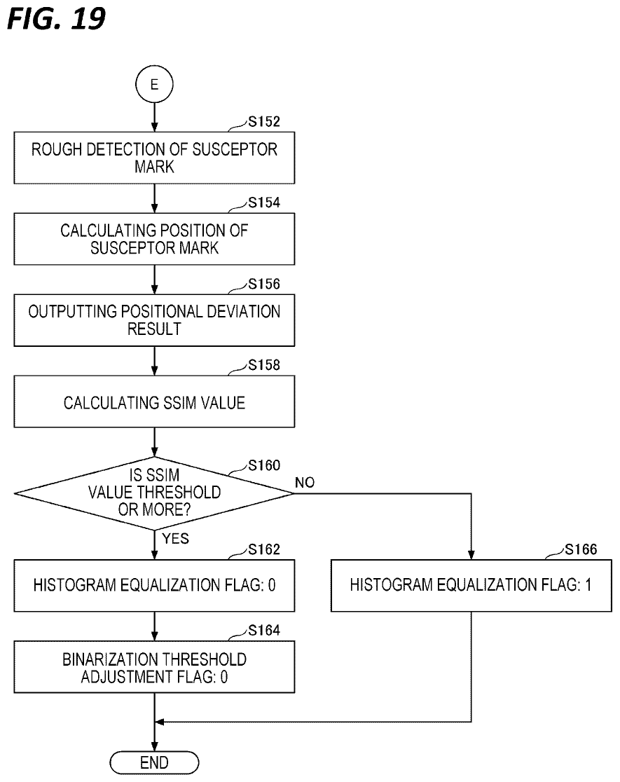

When it is determined in step S130 that the rough detection of the susceptor mark 25 is successful, the mark detection unit 210 proceeds to step S152 of FIG. 19.

In step S152, the mark detection unit 210 performs a precise detection of the susceptor mark 25. In step S154, the position calculation unit 212 calculates the position of the susceptor mark 25 from the region of the susceptor mark 25 detected by the mark detection unit 210. In step S156, the position calculation unit 212 calculates a positional deviation of the susceptor 2 used for positioning the susceptor 2.

In step S158, the similarity calculation unit 214 calculates the SSIM value as an example of the index of similarity between the image of the susceptor mark 25 included in the current image of the camera 140 and the image of the susceptor mark 25 included in the reference image of the camera 140.

In step S160, the determination unit 216 determines whether the SSIM value calculated by the similarity calculation unit 214 is a threshold or more. When it is determined that the SSIM value is the threshold or more, the determination unit 216 determines that the image of the susceptor mark 25 included in the current image of the camera 140 has not deteriorated, and proceeds to step S162.

In step S162, the determination unit 216 sets “0” for the histogram equalization flag to indicate the state where the histogram equalization process is not needed. In step S164, the determination unit 216 sets “0” for the binarization threshold adjustment flag to indicate the state where the binarization threshold adjustment process is not needed.

Meanwhile, when it is determined that the SSIM value is not the threshold or more, the determination unit 216 determines that the image of the susceptor mark 25 included in the current image of the camera 140 has deteriorated, and proceeds to step S166. In step S166, the determination unit 216 sets “1” for the histogram equalization flag to indicate the state where the histogram equalization process is needed.

According to the process of the flowcharts illustrated in FIGS. 16 to 19, the deterioration of the image of the susceptor mark 25 included in the current image of the camera 140 may be determined based on the SSIM value for the image of the susceptor mark 25 included in the current image of the camera 140 and the image of the susceptor mark 25 included in the reference image. When the image of the susceptor mark 25 included in the current image deteriorates, the adaptive histogram equalization process, the shutter speed adjustment process, and the binarization threshold adjustment process are performed in combination for the next current image of the camera 140 to enhance the contrast of the image of the susceptor mark 25 included in the next current image, so that the precision for the detection of the region of the susceptor mark 25 may be improved.

In the embodiment described above, the process performed by the substrate position detecting apparatus 170 of the substrate processing apparatus 180 may be performed by another information processing apparatus connected to the substrate position detecting apparatus 170 for data communication.

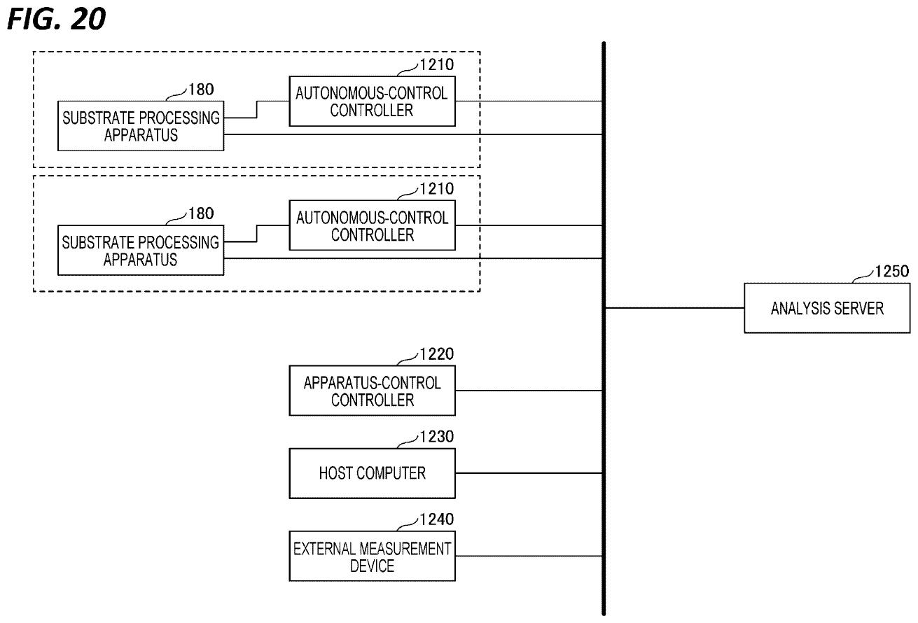

FIG. 20 is a view illustrating an example of the configuration of a substrate processing system according to the present embodiment. As illustrated in FIG. 20, the substrate processing system includes the substrate processing apparatus 180, an autonomous-control controller 1210, an apparatus-control controller 1220, a host computer 1230, an external measurement device 1240, and an analysis server 1250. The substrate processing apparatus 180, the autonomous-control controller 1210, the apparatus-control controller 1220, the host computer 1230, the external measurement device 1240, and the analysis server 1250 are connected to each other for communication via a network such as a local area network (LAN).

The substrate processing apparatus 180 executes a process according to control commands (process parameters) output from the apparatus-control controller 1220. The autonomous-control controller 1210 is a controller for the autonomous control of the substrate processing apparatus 180, and performs, for example, a simulation of the state of a process being executed in the substrate processing apparatus 180 using a simulation model.

The autonomous-control controller 1210 is provided for each substrate processing apparatus 180. The autonomous-control controller 1210 performs at least part of the process performed by the substrate position detecting apparatus 170 in the embodiment described above.

The apparatus-control controller 1220 is a controller with a computer configuration to control the substrate processing apparatus 180. The apparatus-control controller 1220 outputs process parameters for controlling the controllable components of the substrate processing apparatus 180, to the substrate processing apparatus 180. The host computer 1230 is an example of a man-machine interface (MMI) that accepts instructions for the substrate processing apparatus 180 from the user such as the operator, and provides information about the substrate processing apparatus 180 to the user such as the operator.

The external measurement device 1240 is a measuring instrument that measures results after execution of a process according to process parameters, such as a film thickness measuring instrument, a sheet resistance measuring instrument, and a particle measuring instrument. For example, the external measurement device 1240 measures the state of attachment of a film onto a wafer W such as a monitor wafer.

The analysis server 1250 performs, for example, a data analysis necessary for a process performed by the autonomous-control controller 1210. The analysis server 1250 may perform a machine learning of a machine learning model for the substrate processing apparatus 180 based on data collected from a plurality of substrate processing apparatuses 180.

The substrate processing system of FIG. 20 is merely an example, and various examples of the system configuration are conceivable according to applications or purposes. The classification of devices in FIG. 20, such as the substrate processing apparatus 180, the autonomous-control controller 1210, the apparatus-control controller 1220, the host computer 1230, the external measurement device 1240, and the analysis server 1250, is merely an example.

For example, the substrate processing system may be configured in various forms, such as, for example, an integrated configuration of at least two of the substrate processing apparatus 180, the autonomous-control controller 1210, the apparatus-control controller 1220, the host computer 1230, the external measurement device 1240, and the analysis server 1250, or a configuration in which these components are further divided.

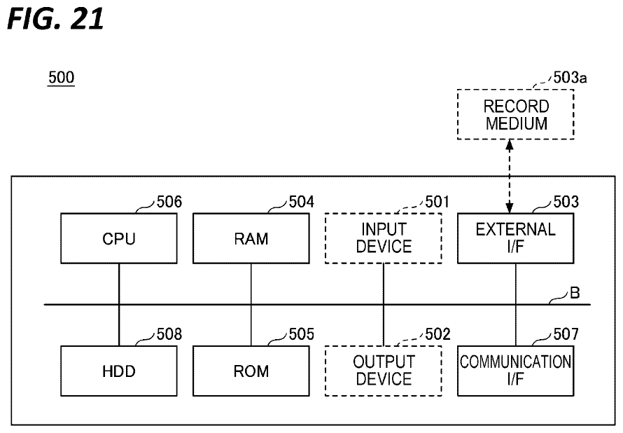

For example, the substrate processing apparatus 180, the autonomous-control controller 1210, the apparatus-control controller 1220, the host computer 1230, the external measurement device 1240, and the analysis server 1250 are implemented by a computer having the hardware configuration illustrated in FIG. 21. Further, the control unit 100 and the processing unit 160 of the substrate processing apparatus 180 described above are also implemented by the computer having the hardware configuration of FIG. 21. FIG. 21 is a hardware configuration diagram of an example of the computer.

The autonomous-control controller 1210, the apparatus-control controller 1220, the host computer 1230, the analysis server 1250, the control unit 100, and the processing unit 160 are an example of an information processing apparatus that detects a predetermined captured image used for positioning the susceptor 2 accommodated in the chamber 1, from the captured image of the interior of the chamber 1.

A computer 500 of FIG. 21 includes, for example, an input device 501, an output device 502, an external I/F 503, a random access memory (RAM) 504, a read only memory (ROM) 505, a central processing unit (CPU) 506, a communication I/F 507, and a hard disk drive (HDD) 508, which are connected to each other via a bus B. The input device 501 and the output device 502 may be connected and used when necessary.

The input device 501 is, for example, a keyboard, a mouse, or a touch panel, and is used when the operator inputs each operation signal. The output device 502 is, for example, a display, and displays results of a process executed by the computer 500. The communication I/F 507 is an interface connecting the computer 500 to a network. The HDD 508 is an example of a nonvolatile storage device that stores programs or data.

The external I/F 503 is an interface to external devices. The computer 500 may perform read and/or write with respect to a record medium 503a such as a secure digital (SD) memory card via the external I/F 503. The ROM 505 is an example of a nonvolatile semiconductor memory (storage device) that stores programs or data. The RAM 504 is an example of a volatile semiconductor memory (storage device) that temporarily stores programs or data.

The CPU 506 is a calculation device that reads programs or data from the storage device such as the ROM 505 or the HDD 508 onto the RAM 504 and executes processes, to implement the control or function of the entire computer 500.

In the substrate processing system of FIG. 20, the autonomous-control controller 1210, the apparatus-control controller 1220, the host computer 1230, the analysis server 1250, the control unit 100, and the processing unit 160 may implement various functions through, for example, the hardware configuration of the computer 500 of FIG. 21.

By using the technology of the embodiment described above, the present disclosure may improve the precision of detection of a predetermined captured image (susceptor mark 25) used for positioning the susceptor 2 from the captured image of the interior of the chamber 1 for substrate processing. Therefore, in the present embodiment, the predetermined captured image used for positioning the susceptor 2 accommodated in the chamber 1 may be obtained with the high contrast, and based on the captured image, the position of a substrate such as a wafer W may be precisely and reliably detected for a long period of time.

According to the present disclosure, it is possible to improve the precision of detection of a predetermined captured image for positioning a susceptor from a captured image of the interior of a substrate processing chamber.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be restricting, with the true scope and spirit being indicated by the following claims.

What is claimed is:

1. An information processing apparatus comprising:
image capturing circuitry configured to capture an image of an interior of a processing chamber of an information processing apparatus through a window provided on a top surface of the processing chamber, thereby allowing the information processing apparatus to detect a predetermined image used for positioning a susceptor accommodated in the processing chamber from the image of the interior of the processing chamber;
similarity calculation circuitry configured to calculate a similarity between a current predetermined image included in the image of the interior of the processing chamber and an original predetermined image;
determination circuitry configured to determine a deterioration of the current predetermined image based on the similarity calculated in the similarity calculation circuitry; and
correction circuitry configured to perform a correction process to improve a precision of detection of the predetermined image based on the deterioration of the current predetermined image determined at the determination circuitry.

2. The information processing apparatus according to claim 1, wherein when the current predetermined image is determined to have deteriorated, the correction circuitry perform the correction process to enhance a contrast of the current predetermined image through a histogram equalization process or an adaptive histogram equalization process, thereby improving the precision of detection of the current predetermined image.

3. The information processing apparatus according to claim 1, wherein the correction circuitry perform the correction process to enhance a contrast of the current predetermined image by adjusting a shutter speed of an image capturing according to the similarity calculated previously at the similarity calculation circuitry, thereby improving the precision of detection of the current predetermined image.

4. The information processing apparatus according to claim 1, wherein the correction circuitry perform the correction process to adjust a binarization threshold used to detect the current predetermined image according to the similarity calculated previously at the similarity calculation circuitry, thereby improving the precision of detection of the current predetermined image.

5. The information processing apparatus according to claim 1, wherein the similarity is an index of a structural similarity (SSIM).

6. The information processing apparatus according to claim 1, wherein the predetermined image used for positioning the susceptor includes a mark provided on a surface of the susceptor.

7. The information processing apparatus according to claim 6, wherein the susceptor is capable of placing a plurality of substrates thereon, and the mark is provided corresponding to each of the plurality of substrates to be placed on the susceptor.

8. A detection method comprising:
providing an information processing apparatus that detects a predetermined image used for positioning a susceptor accommodated in a processing chamber of the information processing apparatus from an image of an interior of the processing chamber captured through a window provided on a top surface of the processing chamber;
calculating a similarity between a current predetermined image included in the image of the interior of the processing chamber and an original predetermined image;
determining a deterioration of the current predetermined image, based on the similarity calculated at the calculating; and
performing a correction process to improve a precision of detection of the predetermined image, based on the deterioration of the current predetermined image determined at the determining.

9. A substrate processing apparatus comprising:
a chamber for processing a substrate;
a susceptor accommodated in the chamber; and
an information processing apparatus configured to detect a predetermined image used for positioning the susceptor from an image of an interior of the chamber captured through a window provided on a top surface of the chamber,
wherein the information processing apparatus includes
similarity calculation circuitry configured to calculate a similarity between a current predetermined image included in the image of the interior of the chamber and an original predetermined image,
determination circuitry configured to determine a deterioration of the current predetermined image based on the similarity calculated at the similarity calculation circuitry; and
correction circuitry configured to perform a correction process to improve a precision of detection of the predetermined image based on the deterioration of the current predetermined image determined at the determination circuitry.
